(19) United States
(12) Patent Application Publication
(10) Pub. No.: US 2026/0173594 A1
(43) Pub. Date: Jun. 18, 2026

(54) NEAR INFRARED LIGHT EMITTING DIODE AND MANUFACTURING METHOD THEREOF

(71) Applicant: Taiwan-Asia Semiconductor Corporation, Hsinchu City (TW)

(72) Inventor: Huang-Ming Chen, Hsinchu City (TW)

(21) Appl. No.: 19/262,413

(22) Filed: Jul. 8, 2025

(30) Foreign Application Priority Data
Dec. 12, 2024 (TW) 113148415

(51) Int. Cl. H10H 20/84; H10H 20/01; H10H 20/824

(52) U.S. Cl. CPC H10H 20/84; H10H 20/034; H10H 20/824

(57) ABSTRACT

A near-infrared (NIR) light-emitting diode (LED) and a manufacturing method thereof are provided. The NIR LED includes a substrate, an epitaxial composite layer, an upper electrode, and a black photoresist. The epitaxial composite layer is disposed on the substrate and comprises a light-emitting layer with an emission wavelength ranging from 750 nanometers (nm) to 1000 nm. The upper electrode is disposed on the top surface of the epitaxial composite layer. The black photoresist encapsulates the epitaxial composite layer while exposing only the upper electrode wherein the black photoresist absorbs visible light within the emission wavelength range and allows only the infrared light to pass through and be emitted externally.

### CROSS-REFERENCES TO RELATED APPLICATIONS

This application claims the benefit of priority to Taiwanese Patent Application No. 113148415 filed on Dec. 12, 2024, which is hereby incorporated by reference in its entirety.

### BACKGROUND OF THE INVENTION

### Field of the Invention

The present invention relates to a near-infrared light-emitting diode and a method for manufacturing the same, and in particular to a near-infrared light-emitting diode capable of suppressing the red glow phenomenon and a method for manufacturing the same.

### Descriptions of the Related Art

The application scope of near-infrared (NIR) light-emitting diodes (LEDs) has become increasingly widespread, covering fields such as communications, medical, industrial, and consumer electronics. For example, in the field of optical communications, near-infrared LEDs provide a stable and low-energy light source with primary wavelength ranges of 850 nanometers (nm) and 940 nanometers (nm), suitable for high-frequency modulated signals and short-distance data transmission, such as fiber-optic communications and high-speed local area networks. Alternatively, in medical applications, near-infrared LEDs have the ability to penetrate skin, making them suitable for measuring blood oxygen saturation and heart rate. They have been applied in wearable devices for blood oxygen and heart rate monitoring.

However, the commonly used wavelength bands for near-infrared light, such as 850 nm and 940 nm, have emission spectra that are very close to or even partially overlap with the visible light wavelength range of 700 nm or shorter. If the module packaging is poor, this can easily lead to the “red glow phenomenon,” where red light is visible to the human eye in dark environments. To avoid the red glow phenomenon caused by visible light, encapsulating resin or packaging modules is typically used for near-infrared LED application modules for blocking light. While this method can block visible light, it also tends to shield near-infrared light, significantly reducing the brightness of the near-infrared LED. Additionally, external encapsulating resin in near-infrared LEDs often suffers from light leakage due to external factors, leading to poor reliability of application module products. To address these issues, there is an urgent need in the industry for an innovative near-infrared LED structure to mitigate the red glow phenomenon and overcome light leakage issues caused by poor packaging.

### SUMMARY OF THE INVENTION

The main objective of the present invention is to provide an innovative near-infrared light-emitting diode and a method for manufacturing the same. Compared to conventional optoelectronic components, the present invention utilizes a black photoresist to encapsulate the epitaxial layer of the near-infrared LED. By leveraging the black photoresist's ability to effectively absorb visible light while allowing infrared light to penetrate, the invention achieves the goals of suppressing the red glow phenomenon and maintaining high brightness.

To achieve the above objective, the present invention provides a near-infrared light-emitting diode comprising a substrate, an epitaxial composite layer, an upper electrode, and a black photoresist. The epitaxial composite layer is disposed on the substrate and includes a light-emitting layer with an emission wavelength ranging from 750 nanometers (nm) to 1000 nanometers (nm). The upper electrode is disposed on the top surface of the epitaxial composite layer. The black photoresist encapsulates the epitaxial composite layer while exposing only the upper electrode, thereby absorbing visible light within the emission wavelength and allowing only infrared light to penetrate the black photoresist and be emitted outward.

In an embodiment of the near-infrared light-emitting diode of the present invention, the wavelength band of the infrared light penetrating the black photoresist and emitted outward is 850 nanometers (nm) to 940 nanometers (nm).

In an embodiment of the near-infrared light-emitting diode of the present invention, the thickness of the black photoresist is approximately 1 to 5 micrometers (μm).

In an embodiment of the near-infrared light-emitting diode of the present invention, the materials of the black photoresist comprise 1-Methoxy-2-propanol acetate and Cyclohexanone.

In an embodiment of the near-infrared light-emitting diode of the present invention, the epitaxial composite layer further comprises a P-type epitaxial layer and an N-type epitaxial layer sandwiching the light-emitting layer.

In an embodiment of the near-infrared light-emitting diode of the present invention, the material of the P-type epitaxial layer and the N-type epitaxial layer includes gallium arsenide (GaAs) or aluminum gallium arsenide (AlGaAs), and the material of the light-emitting layer includes indium gallium arsenide (InGaAs) or aluminum gallium arsenide (AlGaAs).

In an embodiment of the near-infrared light-emitting diode of the present invention, the substrate is a gallium arsenide (GaAs) substrate or a silicon (Si) substrate.

To achieve the above objective, the present invention provides a method for manufacturing a near-infrared light-emitting diode, comprising the following steps: providing an epitaxial composite layer disposed on a substrate, the epitaxial composite layer comprising a light-emitting layer with an emission wavelength ranging from 750 nanometers (nm) to 1000 nanometers (nm); providing an upper electrode disposed on the top surface of the epitaxial composite layer; and providing a black photoresist encapsulating the epitaxial composite layer while exposing only the upper electrode, thereby absorbing visible light within the emission wavelength and allowing only infrared light to penetrate the black photoresist and be emitted outward.

In an embodiment of the method for manufacturing a near-infrared light-emitting diode of the present invention, the step of providing a black photoresist is to provide a black photoresist with a thickness of approximately 1 to 5 micrometers (μm), wherein the materials of the black photoresist comprise 1-Methoxy-2-propanol acetate and Cyclohexanone.

In an embodiment of the method for manufacturing a near-infrared light-emitting diode of the present invention, the step of providing an epitaxial composite layer is to provide a P-type epitaxial layer and an N-type epitaxial layer sandwiching the light-emitting layer.

In an embodiment of the method for manufacturing a near-infrared light-emitting diode of the present invention, the material of the P-type epitaxial layer and the N-type epitaxial layer includes gallium arsenide (GaAs) or aluminum gallium arsenide (AlGaAs), and the material of the light-emitting layer includes indium gallium arsenide (InGaAs) or aluminum gallium arsenide (AlGaAs).

In an embodiment of the method for manufacturing a near-infrared light-emitting diode of the present invention, the substrate is a gallium arsenide (GaAs) substrate or a silicon (Si) substrate.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 and FIG. 2 illustrate schematic diagrams of the manufacturing process of a near-infrared light-emitting diode according to an embodiment of the present invention;

FIG. 3 illustrates a top-view schematic diagram of a near-infrared light-emitting diode according to an embodiment of the present invention;

FIG. 4 illustrates a cross-sectional schematic diagram along line AA in FIG. 3; and

FIG. 5 illustrates a schematic diagram of the process steps for manufacturing a near-infrared light-emitting diode according to an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

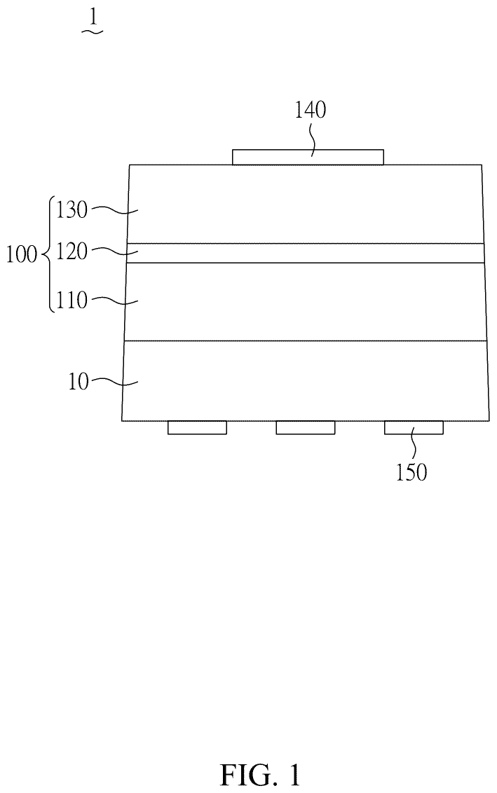

Referring to FIG. 1, a schematic diagram illustrates a manufacturing process of a near-infrared light-emitting diode 1 according to an embodiment of the present invention. In this embodiment, a substrate 10 is first provided, preferably an opaque substrate, such as a gallium arsenide (GaAs) substrate or a silicon (Si) substrate. Next, an epitaxial composite layer 100 is formed on the substrate 10, comprising an N-type epitaxial layer 110, a light-emitting layer 120, and a P-type epitaxial layer 130. Specifically, the light-emitting layer 120 is formed of a multiple quantum well (MQW) structure made of a ternary compound semiconductor, such as indium gallium arsenide (InGaAs) or aluminum gallium arsenide (AlGaAs), sandwiched between the N-type epitaxial layer 110 and the P-type epitaxial layer 130. In this embodiment, the emission wavelength of the multiple quantum well ranges from 750 nanometers (nm) to 1000 nanometers (nm), providing infrared light primarily in the wavelength bands of 850 nm or 940 nm.

Additionally, the N-type epitaxial layer 110 is an N-type gallium arsenide (GaAs) layer or an N-type aluminum gallium arsenide (AlGaAs) layer, and the P-type epitaxial layer 130 is a P-type gallium arsenide (GaAs) layer or a P-type aluminum gallium arsenide (AlGaAs) layer. It should be noted that the materials described in this embodiment are merely exemplary, and the present invention is not limited thereto. In practical applications, materials and their compositions can be adjusted based on the emission wavelength, such as using gallium phosphide (GaP), indium phosphide (InP), or indium gallium arsenide (InGaAs) for the epitaxial layers. Subsequently, an electrode metallization process is performed to form an upper electrode 140 on the epitaxial composite layer 100 and a lower electrode 150 on the backside of the substrate 10. The materials for the upper electrode 140 and lower electrode 150 may include, for example, germanium-gold (GeAu), germanium-gold-nickel (GeAuNi), or germanium-titanium-platinum-gold (GeTiPtAu).

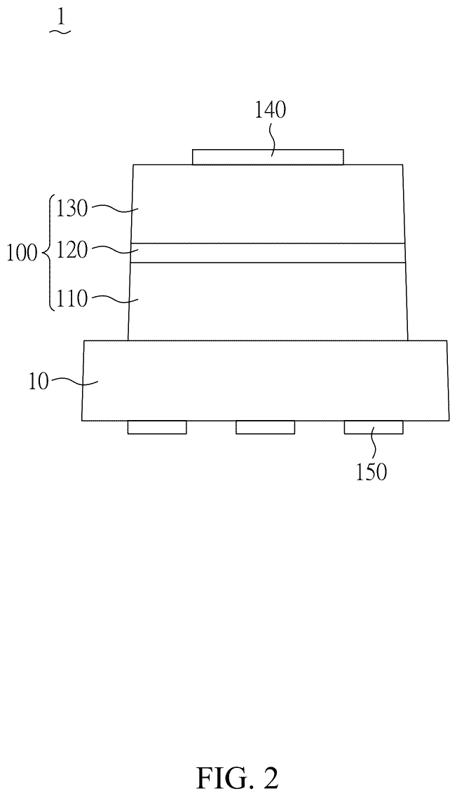

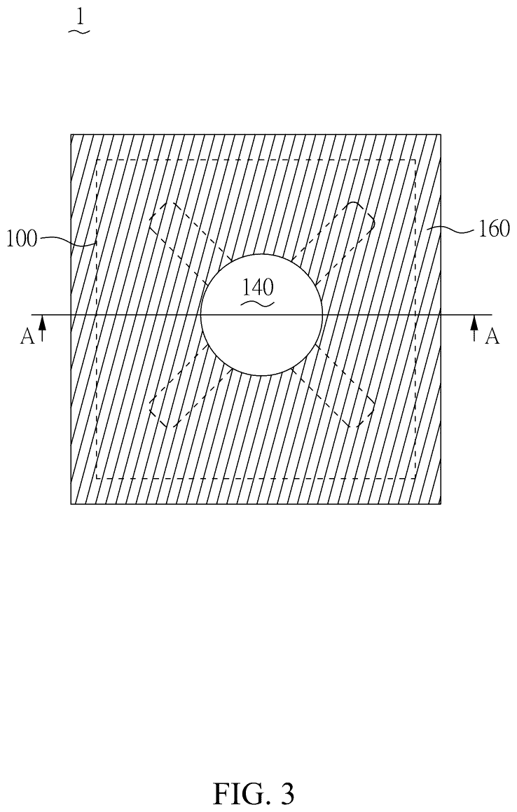

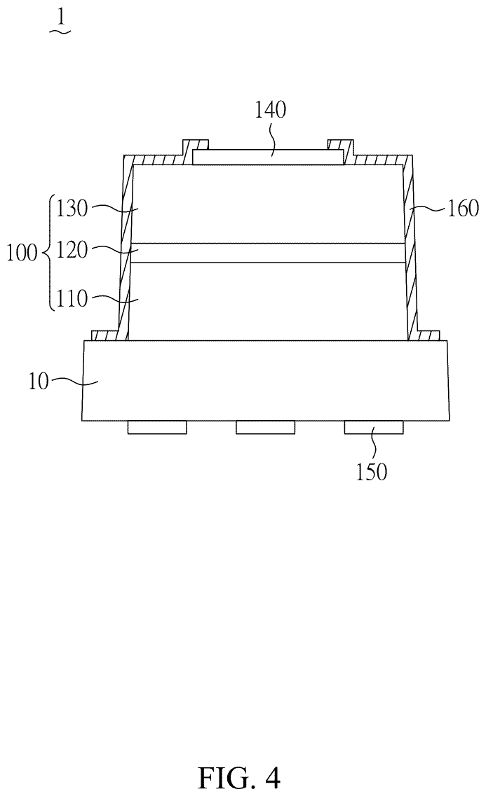

Referring to FIG. 2, a protective layer (not shown) is formed on the surface of the device, followed by a mesa etching process to etch portions of the epitaxial composite layer 100. Specifically, portions of the N-type epitaxial layer 110, the light-emitting layer 120, and the P-type epitaxial layer 130 are etched to form a mesa structure of the epitaxial composite layer on the substrate 10. Next, referring to FIG. 3 and FIG. 4 together, FIG. 3 illustrates a top-view schematic diagram of the near-infrared light-emitting diode 1 according to an embodiment of the present invention, and FIG. 4 illustrates a cross-sectional schematic diagram along line AA in FIG. 3. As shown in these figures, a coating process for a black photoresist 160 is then performed to completely encapsulate the epitaxial composite layer 100 while exposing only the upper electrode 140 to facilitate subsequent wire bonding. In a specific embodiment, the material of the black photoresist 160 comprises 1-Methoxy-2-propanol acetate and Cyclohexanone, enabling the absorption of visible light within the emission wavelength of the light-emitting layer 120 while allowing only infrared light to penetrate the black photoresist and be emitted outward. Specifically, the black photoresist 160 can absorb red light at approximately 700 nm, allowing only infrared light primarily in the 850 nm or 940 nm bands to be penetrated, thus ensuring that the near-infrared light-emitting diode 1 of the present invention can suppress the red glow phenomenon associated with conventional near-infrared LEDs. Specifically, the thickness of the black photoresist 160 is approximately 1 to 5 micrometers (μm), preferably 3 micrometers (μm).

It should be emphasized that the black photoresist encapsulating the epitaxial composite layer of the near-infrared light-emitting diode of the present invention is applied at the wafer processing stage. Based on the estimated number of dies on a single wafer, approximately 30,000 to 40,000 near-infrared LED dies can be simultaneously coated with the black photoresist in a single process per wafer. This ensures that the epitaxial layer of each die is fully encapsulated with the black photoresist, absorbing visible light within the emission wavelength while allowing near-infrared light outside the visible spectrum to be emitted outward. In contrast, black encapsulating resin is used for light-blocking processes at the conventional packaging stage, where the light-blocking resin coating can only be applied to a single package at a time, making it impossible to coat multiple packages simultaneously. Therefore, the innovative structure and manufacturing method disclosed in the present invention not only achieve a tight encapsulation with no light leakage and effective suppression for red glow but also offer significantly higher production efficiency and capacity compared to conventional black resin packaging processes.

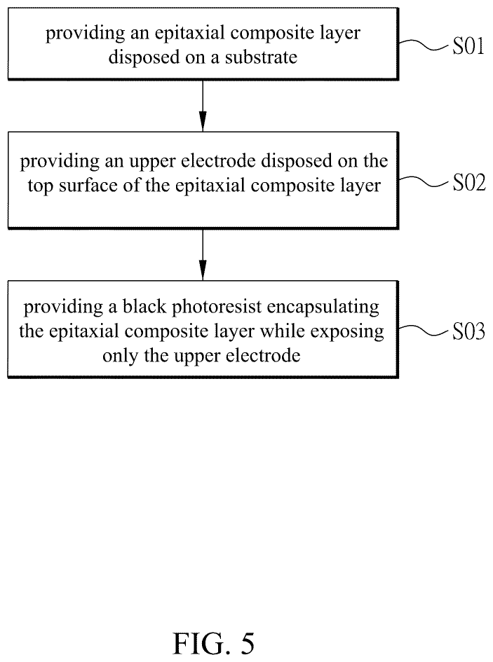

Referring to FIG. 5, a schematic diagram illustrates the process steps for manufacturing the near-infrared light-emitting diode of the present invention. First, in step S01, an epitaxial composite layer is provided, disposed on a substrate, and the epitaxial composite layer comprises a light-emitting layer with an emission wavelength ranging from 750 nanometers (nm) to 1000 nanometers (nm). Next, in step S02, an upper electrode is provided, disposed on the top surface of the epitaxial composite layer. Finally, in step S03, a black photoresist is provided, encapsulating the epitaxial composite layer while exposing only the upper electrode, thereby absorbing visible light within the emission wavelength and allowing only infrared light to penetrate the black photoresist and be emitted outward. Details of the related components are as described above and will not be repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A near-infrared light-emitting diode, comprising:
a substrate;
an epitaxial composite layer disposed on the substrate and comprising a light-emitting layer with an emission wavelength ranging from 750 nm to 1000 nm;
an upper electrode disposed on the top surface of the epitaxial composite layer; and
a black photoresist encapsulating the epitaxial composite layer while exposing only the upper electrode for absorbing visible light within the emission wavelength and allowing only infrared light to penetrate and be emitted outward.

2. The near-infrared light-emitting diode of claim 1, wherein the wavelength band of the infrared light penetrating the black photoresist and emitted outward is 850 nm to 940 nm.

3. The near-infrared light-emitting diode of claim 1, wherein a thickness of the black photoresist is 1 to 5 micrometers (μm).

4. The near-infrared light-emitting diode of claim 1, wherein the materials of the black photoresist comprise 1-Methoxy-2-propanol acetate and Cyclohexanone.

5. The near-infrared light-emitting diode of claim 1, wherein the epitaxial composite layer further comprises a P-type epitaxial layer and an N-type epitaxial layer sandwiching the light-emitting layer.

6. The near-infrared light-emitting diode of claim 5, wherein the material of the P-type epitaxial layer and the N-type epitaxial layer includes gallium arsenide (GaAs) or aluminum gallium arsenide (AlGaAs), and the material of the light-emitting layer includes indium gallium arsenide (InGaAs) or aluminum gallium arsenide (AlGaAs).

7. The near-infrared light-emitting diode of claim 1, wherein the substrate is a gallium arsenide (GaAs) substrate or a silicon (Si) substrate.

8. A manufacturing method of a near-infrared light-emitting diode, comprising:
providing an epitaxial composite layer disposed on a substrate and the epitaxial composite layer comprising a light-emitting layer with an emission wavelength ranging from 750 nm to 1000 nm;
providing an upper electrode disposed on the top surface of the epitaxial composite layer; and
providing a black photoresist encapsulating the epitaxial composite layer while exposing only the upper electrode for absorbing visible light within the emission wavelength and allowing only infrared light to penetrate and be emitted outward.

9. The manufacturing method of a near-infrared light-emitting diode of claim 8, wherein the step of providing a black photoresist is to provide the black photoresist with a thickness of 1 to 5 micrometers (μm) and the materials of the black photoresist comprise 1-Methoxy-2-propanol acetate and Cyclohexanone.

10. The manufacturing method of a near-infrared light-emitting diode of claim 8, wherein the step of providing an epitaxial composite layer is to provide a P-type epitaxial layer and an N-type epitaxial layer sandwiching the light-emitting layer.

11. The manufacturing method of a near-infrared light-emitting diode of claim 10, wherein the material of the P-type epitaxial layer and the N-type epitaxial layer includes gallium arsenide (GaAs) or aluminum gallium arsenide (AlGaAs), and the material of the light-emitting layer includes indium gallium arsenide (InGaAs) or aluminum gallium arsenide (AlGaAs).

12. The manufacturing method of a near-infrared light-emitting diode of claim 8, wherein the substrate is a gallium arsenide (GaAs) substrate or a silicon (Si) substrate.
